(19) United States
(12) Patent Application Publication
(10) Pub. No.: US 2016/0231766 A1
(43) Pub. Date: Aug. 11, 2016

(54) SELF-CALIBRATION CURRENT SOURCE SYSTEM

(71) Applicant: XINFENG QUANTEL TECHNOLOGIES (BEIJING) CO., LTD., Haidian District, Beijing (CN)

(72) Inventors: Ke WU, Beijing (CN); Song LIU, Beijing (CN); Feiqin YANG, Beijing (CN)

(21) Appl. No.: 14/763,958

(22) PCT Filed: Jan. 28, 2013
(86) PCT No.: PCT/CN2013/071052

§ 371 Date: Nov. 10, 2015

(51) Int. Cl. G05F 3/02; H03M 1/10

(52) U.S. Cl. CPC G05F 3/02; H03M 1/1009

(57) ABSTRACT

The present invention provides a self-calibrating current source system, which includes a current source, and further comprises: a self-calibrating resistors array disposed in such a way that the self-calibrating resistors array is associated with an internal resistors array of said current source; a comparator for comparing the voltage of the self-calibrating resistors array with the voltage of the output terminal resistance of said chip; a control module for receiving the compared result from said comparator and outputting a control signal to control the self-calibrating resistors array and said internal resistors array in association with it. The self-calibrating current source system according to the invention may automatically adjust to enable the internal resistors array to be identical to the resistor of the output terminal resistance.

### FIELD OF INVENTION

The present invention relates to the technologies relating to current source, more particularly, to the designing of the reference resistance of current source.

### BACKGROUND

The development of the integrated circuit industry conforms to Moore's law, that is to say, the industrial size reduces at the rate of 30% per generation, while the density of the integrated circuit increases at twice that pace and the performance of the transistor is ensured to be steadily improved. However, the diminishing in industrial size leads to greater process fluctuations, which stems from the manufacturing procedures.

FIG. 1 is a conventional high precision current source, which is for example applied in an analog-to-digital converter (ADC) chip with low-voltage differential signaling digital output. In the conventional current source illustrated, VGB is the output voltage of the internal energy gap circuit of said ADC chip, and Rexternal 12 is a high precision resistor, which is placed outside the current source as a reference resistance. In practical, installing the external resistor Rexternal 12 on the exterior of the chip pins may not be allowed under all scenarios. The external resistor Rexternal 12 will have to be replaced by an internal resistor of said chip if Rexternal 12 fails to be installed, so that the output Iout of the current source is rendered to be extremely sensitive to the process, the voltage and the temperature (PVT: Process, Voltage, Temperature).

Therefore, the feature of the current source in relation to a CMOS process will fluctuate with the variation of the process, the temperature, and the voltage if no external reference resistance is provided. In certain cases, the analog core module of a high speed, high precision analog-to-digital converter which employs said current source, such as a sampling holding circuit and the like, will face severely performance declining.

### SUMMARY OF INVENTION

In view of this, a self-calibrating current source system is provided by the present invention, which may be applied in an analog-to-digital converter chip with low-voltage differential signaling digital output. The self-calibrating current source system includes a current source, and further comprises: a self-calibrating resistors array, which is disposed in such a way that the self-calibrating resistors array is associated with an internal resistors array of said current source; a comparator for comparing the voltage of said self-calibrating resistors array with the voltage of the output terminal resistance of said chip; a control module for receiving the compared result from said comparator, and outputting a control signal to control the self-calibrating resistors array and the internal resistors array associated with said self-calibrating resistors array.

Preferably, in the self-calibrating current source according to the invention, unit resistors in said self-calibrating resistors array corresponds one to one with unit resistors in the internal resistors array.

Preferably, in the self-calibrating current source illustrated in the invention, a resistance of respective unit resistors in said internal resistors array is k times of a resistance of its corresponding unit resistor in the self-calibrating resistors array.

Preferably, the self-calibrating current source system depicted in the invention further includes a first group of switch devices disposed between said internal resistors array and said control module, and switched on or off based upon said control signal; and a second group of switch devices disposed between said self-calibrating resistors array and said control module, and switched on or off based upon said control signal.

Preferably, in the self-calibrating current source system set forth in the invention, each switch devices in said first group of switch devices is disposed separately between one of the unit resistors of said internal resistors array and said control module, and each switch devices in said second group of switch devices is installed separately between one of the unit resistors of said internal resistors array and said control module, such that the switch devices in the first group of switch devices are corresponded one to one with the switch devices in the second group of switch devices.

Preferably, in the self-calibrating current source system elaborated in the invention, the control signal to each switch device in the first group of switch devices is the same as the control signal to the corresponding switch device in the second set of switch devices.

Preferably, in the self-calibrating current source system described in the invention, said control module comprises an inverse counter and control logics.

Preferably, in the self-calibrating current source system described in the invention, said comparator is a double differential clock latched comparator.

In the current source system set forth in the invention, the existing standard port, i.e. the output terminal resistance, is considered as the reference resistance, and the voltage of which is compared with the voltage of the disposed self-calibrating resistors array associating with the internal resistors array of the current source, and thereby adjusting the internal resistor of the current source based on the compared result. Accordingly, a current source system insensitive to PVT may be controlled and maintained without additionally providing an external resistor at the chip port.

### BRIEF DESCRIPTION OF DRAWINGS

FIG. 1 illustrates a conventional high precision current source.

FIG. 2 illustrates the block diagram of the structure of a self-calibrating current source system according to an embodiment of the invention.

FIG. 3 is the schematic circuit diagram of a specific example of the self-calibrating current source system as showed in FIG. 2.

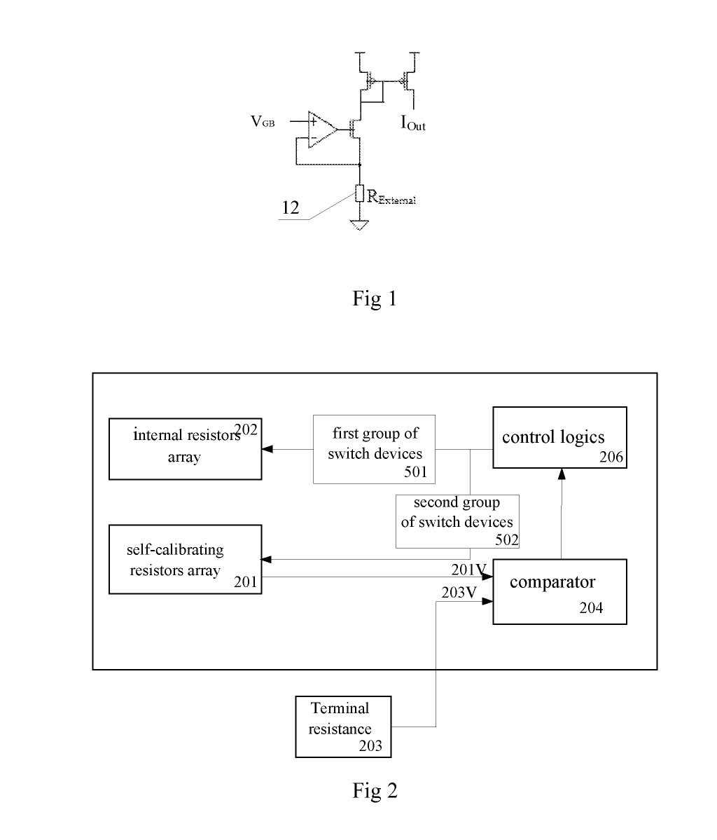

### DESCRIPTION OF EMBODIMENTS

The present invention is now further illustrated in conjunction with the accompanying drawings. It should be appreciated by those skilled in the art that the following is merely a non-limiting illustration of the subject of the present invention in accordance with specific embodiments. The claimed scope of the invention is based on the appended claims. Any modifications or changes without departing from the spirit of the present invention should be contemplated by the claims of the invention.

The present invention focuses on utilizing the existing output terminal resistance of the chip as a reference resistance, whereas installing a self-calibrating resistors array in the interior of the current source, so that the total internal resistance of the current source is rendered to be gradually approximating to the reference resistance.

FIG. 2 illustrates a block diagram of the structure of a self-calibrating current source system according to an embodiment of the invention. By an example, the self-calibrating current source system is discussed below in the an non-limiting example where the self-calibrating current source system is applied in an analog-to-digital converter (ADC) chip with low-voltage differential signaling (LVDS) digital output. For simplicity, the analog-to-digital converter (ADC) chip with low-voltage differential signaling (LVDS) digital output is referred to as LVDS ADC chip hereinafter.

As showed in FIG. 2, the self-calibrating current source system 20 applied in a LVDS ADC chip comprises a fundamental structure of the current source, a self-calibrating resistors array 201, a voltage comparator 204 and a control module 206. The fundamental structure of the current source is substantially the same as a conventional current source. Considering the fundamental structure of the current source is not the emphasis of the invention per se, the descriptions for that structure will be omitted herein. The self-calibrating resistors array 201 is associated with the internal resistors array 202 of the current source, whereby the controlling effect on the self-calibrating resistors array 201 from the control module 206 can also be applied to the internal resistors array 202 associatedly. The voltage 201V of the self-calibrating resistors array 201 and the voltage 203V of the output terminal resistance 203 of the LVDS ADC chip are fed to the voltage comparator 204. The comparator 204 compares the voltages 202V with 203V, and transmits the comparison result to the control module 206. The control module 206 controls the self-calibrating resistors array based upon this comparison result, and simultaneously controls the internal resistors array 202 associated with said self-calibrating resistors array 201, such that the total resistance of said internal resistors array approximate to the resistance of the output terminal resistance 203 of the LVDS ADC chip.

As an example, the control module 206 is electrically connected to the internal resistors array 202 by a first group of switch devices 501, and is electrically connected to the self-calibrating resistors array 201 by a second group of switch devices 502. Both the first group of switch devices 501 and the second group of switch devices 502 receive the control signal from the control module 206, and switch on or off in accordance with this signal. The self-calibrating resistors array 201 is disposed in such a way that the self-calibrating resistors array 201 can correspond to the internal resistors array of said current source according to an embodiment of the invention. As such, when any one of the unit resistors of the self-calibrating resistors array is controlled by the control module, the unit resistor in the internal resistors array which is disposed to correspond to the unit resistor controlled is also controlled. The unit resistor in the self-calibrating resistors array 201 can be a resistor, and can also be a unit formed by a plurality of resistors in series or in parallel. In any example herein, a unit resistor is a unit array composing the resistors array.

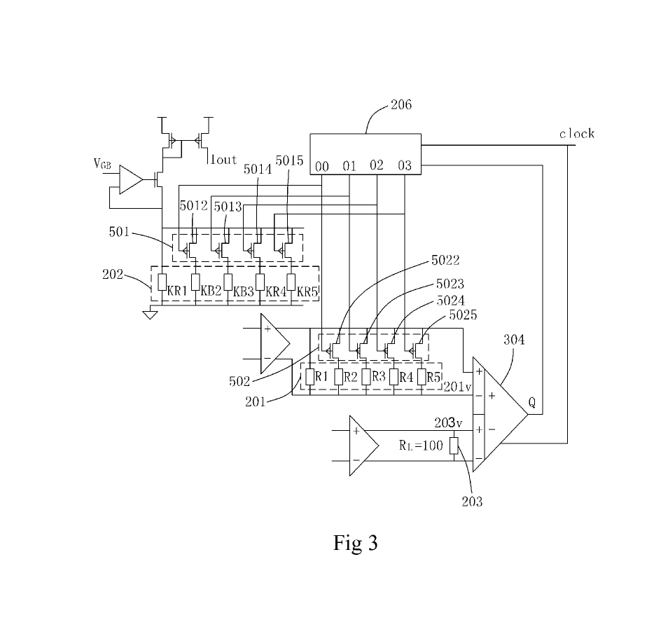

FIG. 3 is the schematic circuit diagram of a specific example of the self-calibrating current source system as showed in FIG. 2. In this example, the voltage comparator 204 is implemented as a double differential clock latched comparator 304, and the control module 206 may be constituted of an inverse counter and control logics. As shown in the FIG. 3, the internal resistors array 202 comprises parallel resistors kR1, kR2, kR3, kR4, and kR5, with the resistor kR2, kR3, kR4, and kR5 being electrically connected with the control module 206 by the first group of switch devices 501, for example, the resistor kR2, kR3, kR4, and kR5 are electrically connected with the control module 206 by the first switch devices 5012, 5013, 5014, 5015, respectively, in which each of the first switch devices is for example a PMOS transistor. The self-calibrating resistors array 201 in this example is implemented as follows: the self-calibrating resistors array 201 is disposed at the grounding terminals of the fundamental structure of the current source in manner of corresponding to the internal resistors array 202, the self-calibrating resistors array 201 includes 5 parallel unit resistors which sequentially are the calibrating resistor R1, R2, R3, R4 and R5; the resistance of the resistor kR1 of the internal resistors array 202 is k times of the resistor R1 of the self-calibrating resistors array 201, the resistance of the resistor kR2 of the internal resistors array 202 is k times of the resistor R2 of the self-calibrating resistors array 201, and so forth, the resistor kR3 is k times of the resistor R3, the resistor kR4 is k times of the resistor R4, and the resistor kR5 is k times of the resistor R5. The resistor R2, R3, R4, and R5 in the self-calibrating resistors array 201 are electrically connected with the control module 206 by the second group of switch devices 502. For example, the resistor R2, R3, R4, and R5 in the self-calibrating resistors array 201 are electrically connected with the control module 206 by the second switch devices 5022, 5023, 5024, 5025, respectively, in which each of the second switch devices can be a PMOS transistor for example. Both the switch device 5012 of the first group of switch devices 501 and the switch device 5022 of the second group of switch devices 502 are electrically connected to the first controlling terminal 00 of the control module 206, both the switch device 5013 of the first group of switch devices 501 and the switch device 5023 of the second group of switch devices 502 are electrically connected to the second controlling terminal 01 of the control module 206, both the switch device 5014 of the first group of switch devices 501 and the switch device 5024 of the second group of switch devices 502 are electrically connected to the third controlling terminal 02 of the control module 206, and both the switch device 5015 of the first group of switch devices 501 and the switch device 5025 of the second group of switch devices 502 are electrically connected to the fourth controlling terminal 03 of the control module 206, whereby the control module 206 can control both the self-calibrating resistors array 201 and the internal resistors array 202 at the same time. In this example, the resistor kR1, kR2, kR3, kR4 and kR5 are the unit resistors composing the internal resistors array, and the resistor R2, R3, R4, and R5 are the unit resistors composing the self-calibrating resistors array.

The voltage of the self-calibrating resistance array 201 is I0×RT, wherein I0 is the driving current of the direct current output of the LVDS and RT is the total resistance of the self-calibrating resistors array 201. The external output terminal resistance 203 of the LVDS ADC chip is RL, the voltage of which is I0×RL, wherein I0 is the driving current of the direct current output of the LVDS and RL is the resistance of the terminal resistance 203. The voltage 201V of the self-calibrating resistors array 201 and the voltage 203V of the terminal resistance 203 are fed to the double differential clock latched comparator 304. The comparison result of the double differential clock latched comparator 304 is fed to the control module 206.

By a non-limiting example, when the current source system is powered on, the output of the double differential clock latched comparator 304 is Q and maintains its state during the initial clock period in the case that the clock is 0; at clock=1, the double differential clock latched comparator 304 compares the voltage 201V of the self-calibrating resistors array 201 with the voltage 203V of the terminal resistance 203, and feeds the comparison result Q to the control module 206. As Q=1 occupying two consecutive clock periods, the counter in the control module 206 increases by one; as Q=0 occupying two consecutive clock periods, said counter decrements by one; as Q=1 occupying one clock period and Q=0 in the next clock period, the output terminal 00, 01, 02, and 03 of the control module 206 keep unchanged. One of the control signals is labeled to lock the state of the switch and the self-calibrating resistors array 201 is disabled to save the power, in case that the internal logic circuit of the control module 206 finds out that such output terminal 00, 01, 02, and 03 keep unchanged.

Under the control of the output terminal 00, 01, 02, and 03 of the control module 206, for example, each switch device which is a PMOS switch is on, the total resistance resulting from the internal resistors array kR1, kR2, kR3, kR4 and kR5 gradually approximates to the external resistance RL. In the present invention, the higher the comparing precision between the resistance RT and the resistance RL, i.e. the precision of the double differential clock latched comparator 304, is, the more the number of resistors in the resistors array and the output terminal of the control module 206 are.

As described above, the comparison result between the self-calibrating resistors array and the terminal resistance RL can have effect on the internal resistors array through the control module 206 due to the associating relationship between the self-calibrating resistors array and the internal resistance array. Whereas at the time the internal resistors array is subjected to adjustment, the self-calibrating loop is simultaneously subjected to the effect of the control module 206, and the self-calibrating loop under control will further be compared with the terminal resistance RL, so as to adjust the internal resistors array based upon that comparison result until the resistance of the internal resistors array equals to the terminal resistance RL.

Although the invention has been described in conjunction with the specific examples, it should be appreciated by those skilled in the art that each element in the example should not be limited to the one described herein. Any other element can be employed as long as the required function(s) can be obtained. For example, the first group of switch devices and the second group of switch devices may be other devices which can achieve the on/off function.

1. A self-calibrating current source system, comprising a current source, the self-calibrating current source system further including:
a self-calibrating resistors array disposed in such a way that the self-calibrating resistors array is associated with an internal resistors array of said current source;
a comparator for comparing voltage of the self-calibrating resistors array with voltage of the output terminal resistance of said chip; and
a control module for receiving the compared result from said comparator, and outputting a control signal to control the self-calibrating resistors array and the internal resistors array associated with said self-calibrating resistors array.

2. The self-calibrating current source system of claim 1, wherein unit resistors in said self-calibrating resistors array corresponds one to one with unit resistors in the internal resistors array.

3. The self-calibrating current source system of claim 2, wherein a resistance of each unit resistor in said internal resistors array is k times of resistance of its corresponding unit resistor in the self-calibrating resistors array.

4. The self-calibrating current source system of claim 2, wherein the self-calibrating current source system further comprise:
a first group of switch devices disposed between said internal resistors array and said control module, and switched on or off based upon said control signal; and
a second group of switch devices disposed between said self-calibrating resistors array and said control module, and switched on or off based upon said control signal.

5. The self-calibrating current source system of claim 4, wherein each switch device in said first group of switch devices is disposed separately between one of the unit resistors of said internal resistors array and said control module, and each switch device in said second group of switch devices is installed separately between one of the unit resistors of said internal resistors array and said control module, such that the switch devices in the first group of switch devices are corresponded one to one with the switch devices in the second group of switch devices.

6. The self-calibrating current source system of claim 5, wherein the control signal to each switch device in the first group of switch devices is the same as the control signal to the corresponding switch device in the second set of switch devices.

7. The self-calibrating current source system of claim 1, wherein said control module comprises an inverse counter and control logics.

8. The self-calibrating current source system of claim 1, wherein said comparator is a double differential clock latched comparator.
